(19) United States
(12) Patent Application Publication
(10) Pub. No.: US 2019/0368779 A1
(43) Pub. Date: Dec. 5, 2019

(54) SOLAR DEVICE

(71) Applicant: Pang Mei Sport Co., Ltd., Changhua County (TW)

(72) Inventor: CHIH-LUNG CHEN, Changhua County (TW)

(21) Appl. No.: 15/994,771

(22) Filed: May 31, 2018

(51) Int. Cl. F24S 25/632; F24S 25/61; H01L 31/042; H02S 20/30

(52) U.S. Cl. CPC F24S 25/632; H02S 20/30; H01L 31/042; F24S 25/61

(57) ABSTRACT

A solar device is provided, including: a solar panel assembly which includes a solar panel and a strut, and the solar panel has a solar power conversion face and a connecting portion which is connected to the strut; and a support device which includes a base seat, an engaging portion and a rubber elastic portion, the base seat has a plurality of threaded structures for being screwed to a base surface, the engaging portion is connected to the strut, and the rubber elastic portion is connected to and between the base seat and the engaging portion.

### BACKGROUND OF THE INVENTION

### Field of the Invention

The present invention relates to a solar device.

### Description of the Prior Art

In recent years, more and more countries encourage people to use green energies (for example, solar power) to replace traditional energies (for example, nuclear power, fossil fuels and others). The solar device is mainly used to absorb sunlight and convert to electricity to use by setting a solar penal on a roof of a building or on a solar power support frame.

In prior arts, the solar penal includes a base seat and a support frame which is disposed on the base seat, and the support frame is for the solar penal to be disposed thereon. However, the support frame of the conventional solar penal is made of aluminum alloy which has a poor buffering effect; therefore, when the solar penal is disposed on the base seat, the support frame may swing or shake due to an external force, and the solar penal may not be stably supported.

The present invention has arisen to mitigate and/or obviate the afore-described disadvantages.

### SUMMARY OF THE INVENTION

The major object of the present invention is to provide a solar device, which provides buffering effect and stable support.

To achieve the above and other objects, a solar device is provided, including: a solar panel assembly which includes a solar panel and a strut, and the solar panel has a solar power conversion face and a connecting portion which is connected to the strut; and a support device which includes a base seat, an engaging portion and a rubber elastic portion, the base seat has a plurality of threaded structures for being screwed to a base surface, the engaging portion is connected to the strut, and the rubber elastic portion is connected to and between the base seat and the engaging portion.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIG. 1 is a stereogram of a first preferred embodiment of the present invention;

FIG. 2 is a partially breakdown of the first preferred embodiment of the present invention;

FIG. 3 is a cross-sectional view of the first preferred embodiment of the present invention;

FIG. 4 is a drawing showing a state of the first preferred embodiment of the present invention in use; and

FIG. 5 is a drawing showing a second preferred embodiment of the present invention in use.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

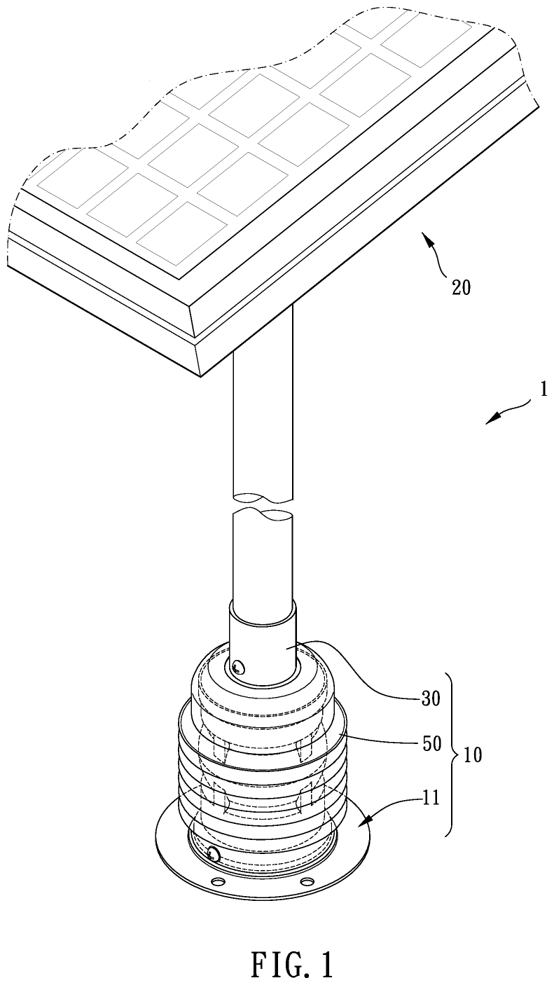

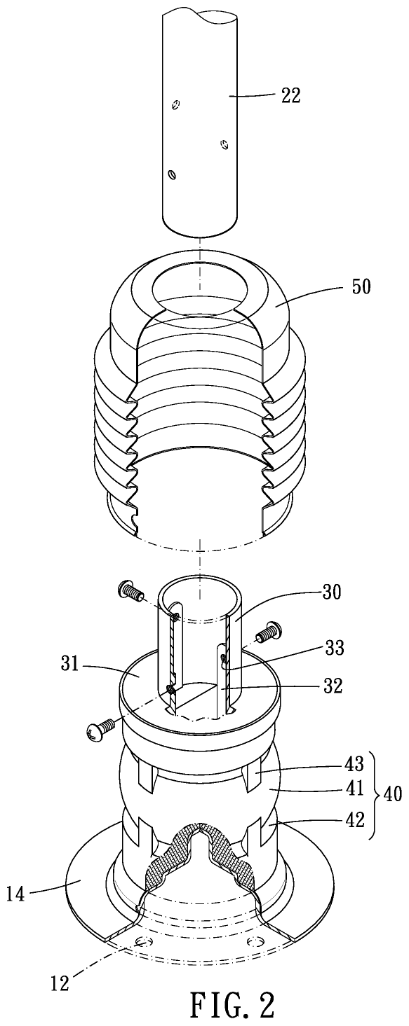

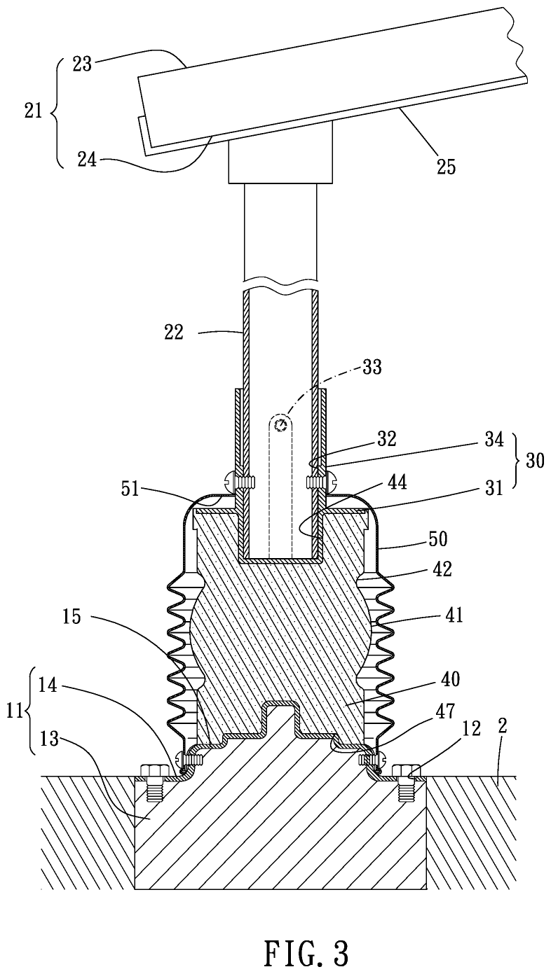

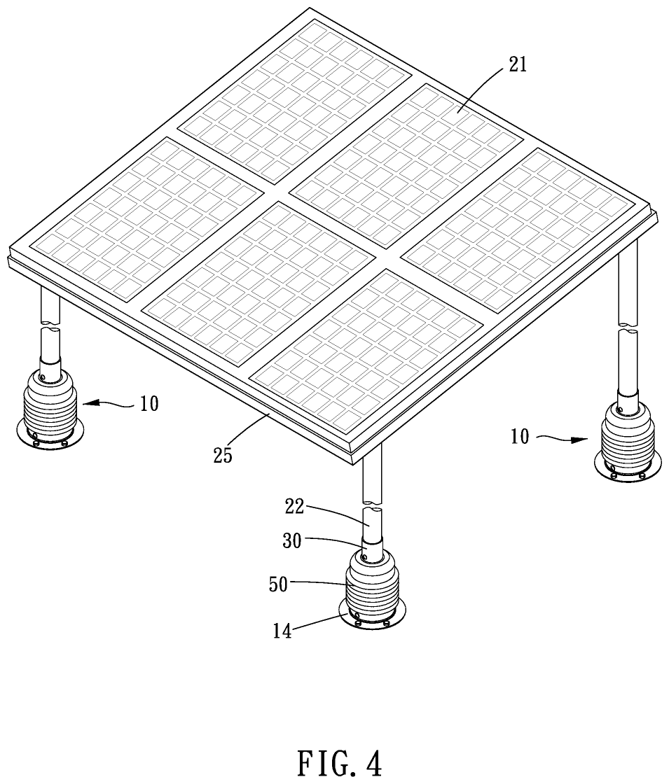

Please refer to FIGS. 1 to 4 for a preferred embodiment of the present invention, a solar device 1 includes a support device 10 and a solar penal assembly 20.

The solar panel assembly 20 includes a solar panel 21 and a strut 22, the solar panel 21 has a solar power conversion face 23 and a connecting portion 24 which is connected to the strut 22, and the solar power conversion face 23 can absorb solar power and convert to electricity; in this embodiment, the connecting portion 24 is a connecting face; and an engaging portion 30 is connected to the strut 22. The support device 10 includes a base seat 11, the engaging portion 30 and a rubber elastic portion 40, the base seat 11 has a plurality of threaded structures 12 for being screwed to a base surface 2 (the base surface 2 may be, for example, a ground surface such as cement surface or a support surface of a transferring device); and the rubber elastic portion 40 is connected to and between the base seat 11 and the engaging portion 30. In this embodiment, the solar penal assembly 20 further includes a frame 25, the solar penal 21 is disposed on the frame 25, and the strut 22 may be connected to the frame 25 to restrict a movement range of the solar penal 21 so as to provide buffering, wind-resistant and earth-resistant effects to stably support the solar device 1. In other embodiments, the strut may further include a universal joint.

In addition, in the present invention, a number of the support device 10 which can be disposed to one said solar penal assembly 20 is not limited. For example, one said solar penal assembly 20 may have either one said support device 10 or a plurality of the support devices 10. Besides, a number of the frame 22 which can be disposed on one said solar penal 21 is not limited.

In this embodiment, the base seat 11 further includes a cement seat 13 and a base 14 which is screwed to the cement seat 13, the plurality of threaded structures 12 are formed on the base 14, and in this embodiment, each said threaded structure 12 is a threaded hole; more specifically, the cement seat 13 can be tightly fixed on the base surface 2. Specifically, the base 14 has the plurality of threaded structures 12 for a plurality of screws to be screwed and connected to the cement seat 13 so that the base 14 can be stably supported and easily disassembled. In addition, the base seat 11 is greater than the rubber elastic portion 40 in outer diameter for providing stable support.

The rubber elastic portion 40 has a curved protrusive section 41 which extends radially to provide buffering effect and support. In this embodiment, the rubber elastic portion 40 is a rubber body which is solid; in other embodiments, the rubber elastic portion may be a rubber body which is hollow, or the rubber elastic portion may include a support rod which is connected to the base seat and the engaging portion and a rubber body which is connected to the base seat and the engaging portion, and the rubber body is circumferentially disposed around the support rod.

The rubber elastic portion 40 further has at least one annular groove 42. In this embodiment, a number of the at least one annular groove 42 is two, the two annular grooves 42 are formed on two opposite sides of the curved protrusive section 41 on an axial direction so that the curved protrusive section 41 can be elastically pressed toward each of the two annular grooves 42 to elevate the buffering effect. In addition, the rubber elastic portion 40 further has a plurality of rib portions 43, each said rib portion 43 is saddled on the at least one annular groove 42 and connected to two opposite sides of the at least one annular groove 42 to provide more preferable and stable support. Specifically, each said rib portion 43 is saddled on one of the two annular grooves 42 and extends toward the axial direction, and preferably, at least one part of each said rib portion 43 is inserted within the at least one annular groove 42 to provide support strength.

Preferably, the rubber elastic portion 40 has a radially outmost point, and the curved protrusive section 41 radially protrudes beyond the radially outmost point to provide greater buffering strength and support.

The solar device 1 further includes an elastic sleeve 50, the elastic sleeve 50 is sleeved on the rubber elastic portion 40, and the elastic sleeve 50 is non-contact with the rubber elastic portion 40. Preferably, the elastic sleeve 50 and the rubber elastic portion 40 are non-contact with each other radially to increase deformation and movement ranges of the elastic sleeve 50. An elastic coefficient of the elastic sleeve 50 and an elastic coefficient of the rubber elastic portion 40 are different to provide different buffering effect. In other embodiments, the elastic sleeve and the rubber elastic portion may have the same elastic coefficient. In this embodiment, the elastic sleeve 50 has an inner protrusive flange 51 extends radially, and the inner protrusive flange 51 covers the rubber elastic portion 40 on an axial direction to provide better protection and prevent the rubber elastic portion 40 from being damaged.

In addition, the engaging portion 30 further includes a protrusive flange 31 which extends radially, and the rubber elastic portion 40 is disposed between the protrusive flange 31 and the base seat 11 to elevate support strength. Furthermore, the engaging portion 30 further includes a tube 34, the strut 22 is detachably connected to the tube 34, and an inner wall of the tube 34 has a plurality of engaging protrusions 32. In this embodiment, each said engaging protrusion 32 has at least one threaded hole 33 so that the strut 22 can be disposed through or sleeved on the tube 34, and the tube 34, the strut 22 and the threaded hole 33 can be screwed via bolts to be detachably positioned.

Preferably, the rubber elastic portion 40 has a recess 44, the tube 34 and the protrusive flange 31 are engaged within the recess 44, and a wall of the recess 44 overlaps with the protrusive flange 31 radially to be stably engaged with each other. In addition, one of the base 14 and the rubber elastic portion 40 has a connecting protrusion, and the other of the base 14 and the rubber elastic portion 40 has a connecting recess which is engaged with the connecting protrusion. In this embodiment, the rubber elastic portion 40 has the connecting recess 47, and the base 14 has the connecting protrusion 15 to increase the engaging strength of the base 14 and the rubber elastic portion 40.

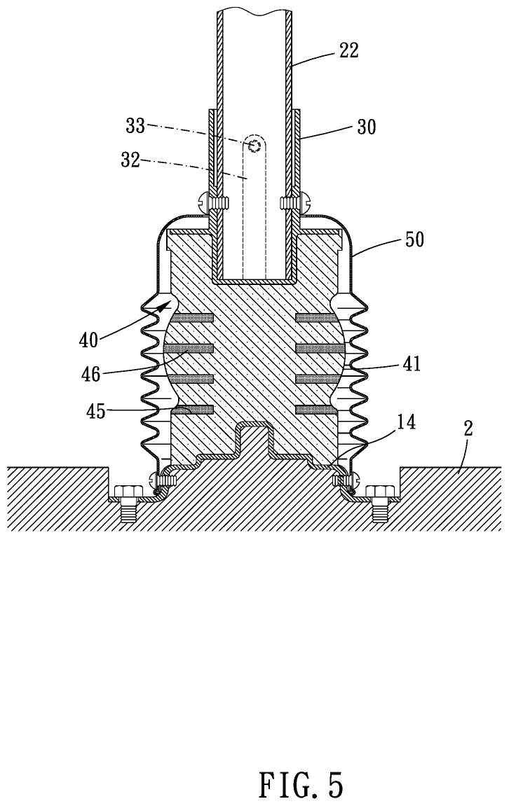

Please refer to FIG. 5, the difference between a second preferred embodiment and the first embodiment is that the curved protrusive section 41 further has a plurality of slots 45 which extend circumferentially and a plurality of elastic bodies 46, and each said elastic body 46 is disposed within each said slot 45; and an elastic coefficient of the plurality of elastic bodies 46 and an elastic coefficient of the rubber elastic portion 40 are different to increase the buffering effect. In other embodiments, each said elastic body may be a metal sheet to provide better support.

Given the above, the rubber elastic portion of the support device can provide buffering, wind-resistant and earth-resistant effects to stably support the solar device.

While we have shown and described various embodiments in accordance with the present invention, it should be clear to those skilled in the art that further embodiments may be made without departing from the scope of the present invention.

What is claimed is:

1. A solar device, including:
a solar panel assembly, including a solar panel and a strut, the solar panel having a solar power conversion face and a connecting portion which is connected to the strut;
a support device, including a base seat, an engaging portion and a rubber elastic portion, the base seat having a plurality of threaded structures for being screwed to a base surface, the engaging portion being connected to the strut, the rubber elastic portion being connected to and between the base seat and the engaging portion.

2. The solar device of claim 1, wherein the rubber elastic portion has a curved protrusive section which extends radially.

3. The solar device of claim 1, wherein the rubber elastic portion further has at least one annular groove.

4. The solar device of claim 3, wherein the rubber elastic portion further includes a plurality of rib portions, each said rib portion is saddled on the at least one annular groove and connected to two opposite sides of the at least one annular groove.

5. The solar device of claim 4, wherein at least a part of each said rib portion is inserted within the annular groove.

6. The solar device of claim 2, wherein the rubber elastic portion has a radially outmost point, and the curved protrusive section radially protrudes beyond the radially outmost point.

7. The solar device of claim 1, further including an elastic sleeve, the elastic sleeve being sleeved on the rubber elastic portion, the elastic sleeve being non-contact with the rubber elastic portion.

8. The solar device of claim 1, wherein the engaging portion further includes a protrusive flange which extends radially, and the rubber elastic portion is disposed between the protrusive flange and the base seat.

9. The solar device of claim 1, wherein the engaging portion further includes a tube, the strut is detachably connected to the tube, and an inner wall of the tube has a plurality of engaging protrusions.

10. The solar device of claim 5, wherein the rubber elastic portion has a curved protrusive section which extends radially; a number of the at least one annular groove is two, the two annular grooves are formed on two opposite sides of the curved protrusive section on an axial direction, and each said rib portion is saddled on one of the two annular grooves and extends toward the axial direction; the rubber elastic portion has a radially outmost point, and the curved protrusive section radially protrudes beyond the radially outmost point; the solar device further includes an elastic sleeve, the elastic sleeve is sleeved on the rubber elastic portion, and the elastic sleeve is radially non-contact with the rubber elastic portion; the engaging portion further includes a protrusive flange which extends radially, and the rubber elastic portion is disposed between the protrusive flange and the base seat; the elastic sleeve has an inner protrusive flange extends radially, and the inner protrusive flange covers the rubber elastic portion on an axial direction; the engaging portion further includes a tube, the strut is detachably connected to the tube, and an inner wall of the tube has a plurality of engaging protrusions; each said engaging protrusion has at least one threaded hole; the base seat further includes a cement seat and a base which is screwed to the cement seat, and the plurality of threaded structures are formed on the base; one of the base and the rubber elastic portion has a connecting protrusion, and the other of the base and the rubber elastic portion has a connecting recess which is engaged with the connecting protrusion; the rubber elastic portion has a recess, the tube and the protrusive flange are engaged within the recess, and a wall of the recess overlaps with the protrusive flange radially; the base seat is greater than the rubber elastic portion in outer diameter; the base has a plurality of threaded structures for a plurality of screws to be disposed therethrough and screwed to the cement seat; the strut further includes a frame; the curved protrusive section further has a plurality of slots which extend circumferentially and a plurality of elastic bodies, and each said elastic body is disposed within each said slot; and an elastic coefficient of the plurality of elastic bodies and an elastic coefficient of the rubber elastic portion are different.
